(19) United States
(12) Patent Application Publication
(10) Pub. No.: US 2015/0195922 A1
(43) Pub. Date: Jul. 9, 2015

(54) METHOD FOR MANUFACTURING WIRING BOARD

(71) Applicant: KYOCERA CIRCUIT SOLUTIONS, INC., Yasu-shi (JP)

(72) Inventor: Masaharu YASUDA, Yasu-shi (JP)

(73) Assignee: KYOCERA CIRCUIT SOLUTIONS, INC., Yasu-shi (JP)

(21) Appl. No.: 14/569,965

(22) Filed: Dec. 15, 2014

(30) Foreign Application Priority Data
Jan. 9, 2014 (JP) 2014-002313

(51) Int. Cl. H05K 3/46

(52) U.S. Cl. CPC H05K 3/4697; H05K 3/4682

(57) ABSTRACT

A method for manufacturing a wiring board includes steps of forming a groove portion in an outer periphery portion of a support metal foil provided metal foil in a shape of frame, in which a metal foil is held on the support metal foil with a release layer interposed between them, mounting the support metal foil provided metal foil on a principal surface of a support board containing an uncured thermosetting resin, pressing and heating them, forming a laminated body on an upper surface of the metal foil located at least in an inside region of the groove portion, cutting out the laminated body and the support board located in the inside region, and separating the laminated body from the support metal foil.

### TECHNICAL FIELD

The present invention relates to a method for manufacturing a wiring board for mounting electronic components such as a semiconductor element.

### BACKGROUND

Conventionally, a buildup wiring board is known as a high density multilayer wiring board for mounting the electronic components such as the semiconductor element. FIG. 5 is a schematic cross-sectional view showing a buildup wiring board 80. As shown in FIG. 5, the buildup wiring board 80 includes a core board 83 which has wiring conductors 82 composed of copper foil, on both surfaces of a glass-resin plate 81. A thickness of the glass-resin plate 81 is about 0.2 mm to 2.0 mm. Thus, insulating layers 84 composed of a resin, and wiring conductors 85 composed of plated films are alternately laminated on both surfaces of the core board 83. A thickness of each of the insulating layer 84 and the wiring conductor 85 is about 10 μm to 100 μm. The buildup wiring board 80 may be manufactured as follows.

First, an insulating sheet is prepared by impregnating a glass cloth with a thermosetting resin such as epoxy resin or bismaleimide triazine resin. Then, copper foil is attached onto both surfaces of the insulating sheet, and the thermosetting resin in the insulating sheet is thermally cured, whereby a double-sided copper-coated plate is provided. A through-hole is formed in the double-sided copper-coated plate so as to penetrate upper and lower surfaces of the plate, and a plated film is deposited on an inner wall of the through-hole, so that the copper foils on the upper and lower surfaces are electrically connected through the plated film in the through-hole. Then, the through-hole is filled with a resin, and the copper foil on each of the upper and the lower surfaces is etched into a predetermined pattern, whereby the core board 83 is provided so as to include the wiring conductor 82 composed of the copper foil on both surfaces of the glass-resin plate 81.

Next, a resin film is prepared by diffusing an inorganic insulating filler in a thermosetting resin such as epoxy resin or bismaleimide triazine resin and attached onto each of the upper and lower surfaces of the core board 83, and the thermosetting resin in the resin film is thermally cured, whereby the insulating layer 84 is formed. Thus, a via-hole is formed in the insulating layer 84 by laser processing, and the wiring conductor 85 composed of a plated film is formed by the semi-additive method on each of the upper and lower surfaces of the insulating layer 84 at the same time including an inner side of the via-hole. Thus, the insulating layers 84 and the wiring conductors 85 are repeatedly formed several times on each of the upper and lower surfaces of the wiring conductor 85. Thus, the buildup wiring board 80 is provided so as to include the core board 83 having the wiring conductors 82 composed of the copper foil on both surfaces of the glass-resin plate 81, the insulating layers 84 composed of the resin, and the wiring conductors 85 composed of the plated film, in which the insulating layers 84 and the wiring conductors 85 are alternately laminated on both surfaces of the core board 83.

The buildup wiring board 80 can attain high density wiring. However, since the thickness of the glass-resin plate 81 is about 0.2 mm to 2.0 mm, there has been a problem that it is difficult to reduce a total thickness of the wiring board 80.

In order to solve the problem, JP 3635219 B1 discloses a method for manufacturing a multilayer board for a semiconductor device by sequentially forming wiring conductors and the insulating layers into multilayer on one surface side of a metal plate from a side of a semiconductor element mounting surface to a side on which an external connection terminal is provided, and then etching away the metal plate. It is described that by this method, the semiconductor element mounting surface can be flat and the thin multilayer board can be provided.

However, according to this method, since it is necessary to etch away a relatively thick metal plate, the etching operation takes a long time. Therefore, the problem is that its productivity is low.

Thus, the applicant of this application has previously proposed a new method for manufacturing a wiring board (JP 2010-56231 A). This method uses a metal foil with a support film in which the metal foil is held on the support film with an adhesive layer interposed between them. More specifically, a groove portion is formed by removing the support film located in an outer periphery portion in a shape of frame, and then the metal foil with the support film is mounted on a principal surface of a support board containing a thermosetting resin in an uncured state so that a metal foil lower surface exposed in the groove portion is opposed to the principal surface of the support board. Next, the metal foil with the support film and the support board are pressed and heated so that the metal foil lower surface exposed in the groove portion is closely attached to the principal surface of the support board, and the support board is thermally cured. Next, insulating layers and conductor layers are alternately laminated in plural on a metal foil upper surface located at least in an inside region of the groove portion, whereby a laminated body for the wiring board is formed so as to be composed of the metal foil, the insulating layers, and the conductor layers. Next, the laminated body and the support board located in the inside region of the groove portion are cut out, and finally, the laminated body is separated from the support film.

According to this method for manufacturing the wiring board, as the support film, a heat resistant resin such as polyethylene terephthalate resin has been used. However, in the case where the support film is composed of the resin, there is a phenomenon in which the support film is shrunk by heat applied when the metal foil with the support film and the support board are pressed and heated, when the support board is thermally cured, or in the step of laminating the insulating layers and the conductor layers. As a result, when the laminated body and the support board located in the inside region of the groove portion are cut out, the laminated body and the support board are largely deflected due to a stress caused by the shrinkage of the support film, so that it is difficult to perform a subsequent process with high accuracy and efficiency.

### SUMMARY

An object of the present invention is to provide a method for manufacturing a wiring board, by which a thin and high density wiring board can be efficiently manufactured.

A method for manufacturing a wiring board according to the present invention includes the following steps of:

forming a groove portion in which a metal foil is exposed, by removing an outer periphery portion of a support metal foil in a shape of frame, the support metal foil holding the metal foil on one surface with a release layer interposed between them;

mounting the support metal foil provided metal foil having the groove portion, on a principal surface of a support board containing an uncured thermosetting resin in such a manner that the lower surface of the metal foil exposed in the groove portion is opposed to the principal surface of the support board;

pressing and heating the support metal foil provided metal foil and the support board to thermally cure the support board in a state in which the lower surface of the metal foil exposed in the groove portion is closely attached to the principal surface of the support board;

forming a laminated body for the wiring board by alternately laminating in plural, insulating layers and conductor layers, on the upper surface of the metal foil located at least in an inside region of the groove portion so as to be composed of the metal foil, the insulating layers, and the conductor layers;

cutting away the laminated body and the support board located in an outside region of the groove portion, from the laminated body and the support board located in an inside region of the groove portion; and

separating the laminated body from the support metal foil.

According to the method for manufacturing the wiring board of the present invention, the thin and high density wiring board can be efficiently manufactured. In addition, the problem that the entire thickness of the wiring board cannot be reduced due to use of the core board may not arise. Furthermore, since the support metal foil provided metal foil and the support board are pressed so that the lower surface of the metal foil exposed in the groove portion is closely attached to the principal surface of the support board, which are heated in this state to thermally cure the support board, the lower surface of the metal foil exposed in the groove portion and the principal surface of the support board are strongly fixed to each other, so that the stability in forming the laminated body can be improved. Furthermore, the support metal foil is not shrunk by heat applied when the support metal foil provided metal foil and the support board are heated and pressed, when the support board is thermally cured, or in the step of laminating the insulating layers and the conductor layers. As a result, even when the laminated body and the support board located in the inside region of the groove portion are cut out, the laminated body and the support board are not largely deflected, so that the subsequent process can be performed with high accuracy and efficiency.

### BRIEF DESCRIPTION OF THE DRAWINGS

FIG. 1A is a schematic cross-sectional view showing a support metal foil provided metal foil according to one embodiment of the present invention, and FIG. 1B is a perspective view of the support metal foil provided metal foil taken from a side of an arrow A in FIG. 1A.

FIGS. 2A to 2K are schematic cross-sectional views for describing a method for manufacturing a wiring board according to one embodiment of the present invention.

FIG. 3 is a schematic cross-sectional view showing a wiring board according to another embodiment of the present invention.

FIGS. 4A and 4B are schematic cross-sectional views for describing a method for manufacturing a wiring board according to still another embodiment of the present invention.

FIG. 5 is a schematic cross-sectional view showing a buildup wiring board.

### DESCRIPTION OF THE PREFERRED EMBODIMENTS

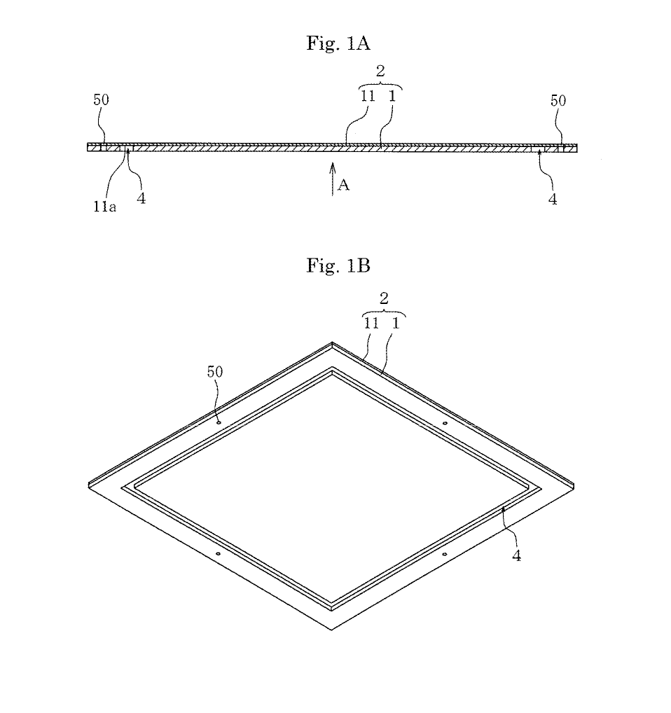

Hereinafter, a method for manufacturing a wiring board according to one embodiment of the present invention will be described in detail with reference to the drawings. FIG. 1A is a schematic cross-sectional view showing a support metal foil provided metal foil according to this embodiment, and FIG. 1B is a perspective view of the support metal foil provided metal foil taken from an arrow A in FIG. 1A. As shown in FIG. 1B, a support metal foil provided metal foil 2 is configured such that a metal foil 11 is held on a support metal foil 1 with a release layer (not shown) interposed between them.

The support metal foil 1 supports the metal foil 11 to prevent the metal foil 11 from being torn or wrinkled so that the metal foil 11 can be easily handled. A thickness of the support metal foil 1 is about 1 μm to 35 μm. The support metal foil 1 is preferably composed of, for example, copper foil.

The metal foil 11 is for providing a conductor layer serving as a starting layer in manufacturing a wiring board. The metal foil 11 is preferably composed of metal with favorable conductivity such as copper (copper foil). A thickness of the metal foil 11 is about 1 μm to 35 μm. Thus, when the metal foil 11 is to be etched away, it can be etched away in a short time. In addition, the metal foil 11 having this thickness is not always required to be completely etched away, but it is etched into a predetermined pattern so as to be favorably used as a part of a wiring conductor (external connection pad).

When the thickness of the metal foil 11 is 1 μm or less, strength of the metal foil 11 is lowered, and workability in alternately laminating in plural, insulating layers and conductor layers on the metal foil 11 could be impaired. In addition, when the thickness of the metal foil 11 is 35 μm or more, the etching away operation takes a long time to finish, which is not preferable.

The release layer is preferably composed of chrome or nickel.

A groove portion 4 is formed by removing the support metal foil 1 in a shape of frame that is located in an outer periphery portion of the support metal foil provided metal foil 2. A lower surface 11a of the metal foil 11 is exposed in the formed groove portion 4. A groove width of the groove portion 4 is preferably about 1 mm to 10 mm. The groove portion may be formed by for example laser processing or the like.

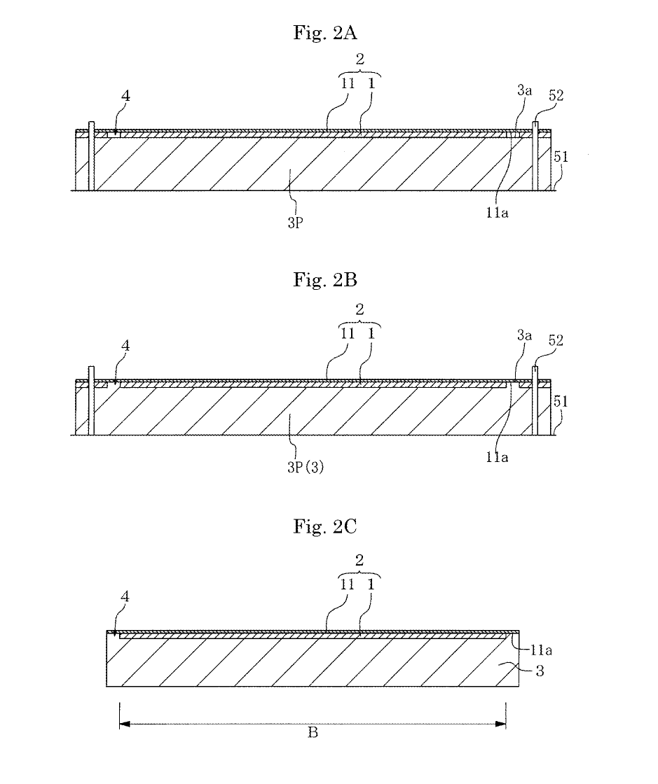

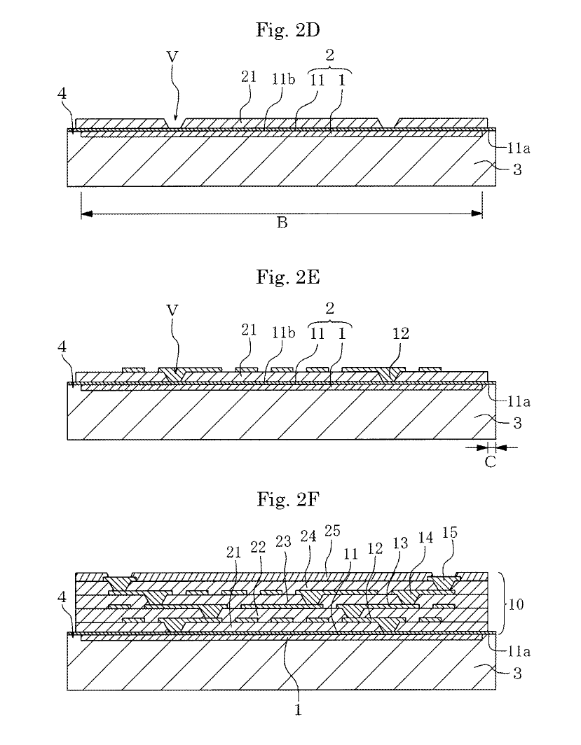

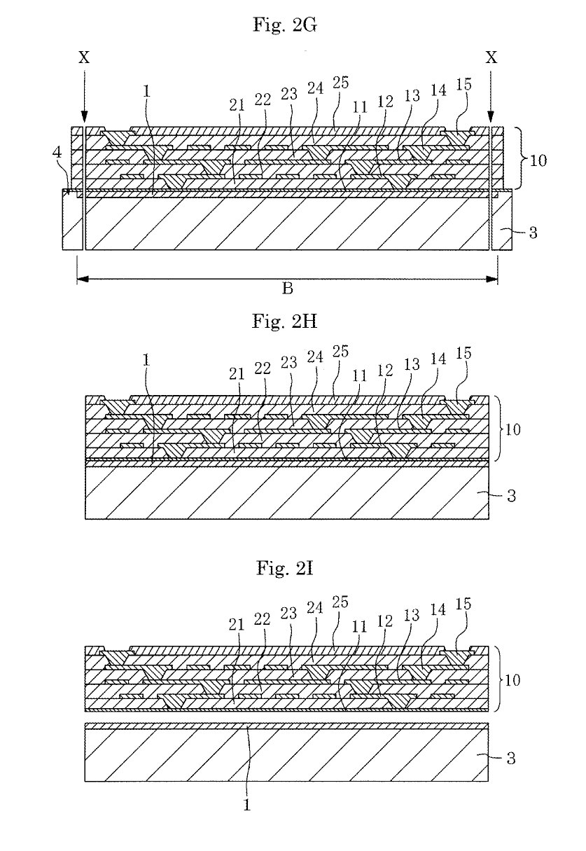

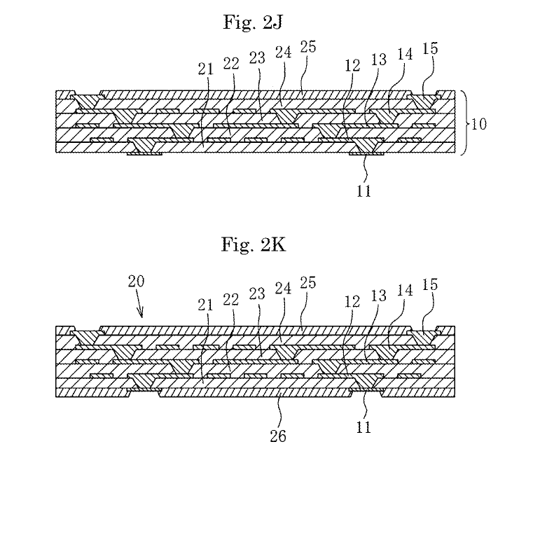

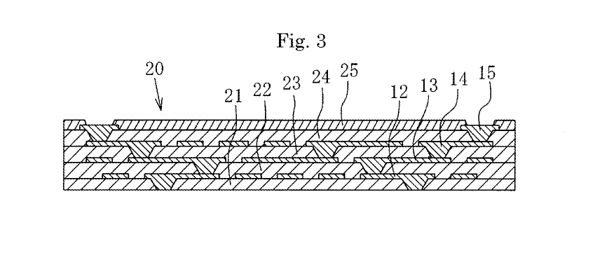

Furthermore, the support metal foil provided metal foil 2 located in an outside region of the groove portion 4 has positioning holes 50 formed in almost its center portions. The positioning holes 50 may be formed by for example laser processing, punching, or drilling from an upper surface toward a lower surface of the support metal foil provided metal foil 2. With the support metal foil provided metal foil 2, the wiring board according to this embodiment is provided through steps shown in FIGS. 2A to 2K.

More specifically, as shown in FIG. 2A, a prepreg 3P is mounted on a base stand 51. The prepreg 3P serves as a support board 3 for supporting a laminated body 10 shown in FIG. 2F so that required flatness can be provided when the laminated body 10 is manufactured, and it contains an uncured thermosetting resin. In addition, a positioning hole is also provided in the prepreg 3P in a position corresponding to the positioning hole 50, and a positioning pin 52 provided in a predetermined position of the base stand 51 is inserted into the positioning hole of the prepreg 3P to be mounted.

This prepreg 3P includes such as a half-cured resin sheet prepared by impregnating a cloth composed of heat-resistant fiber such as glass fiber, with a thermosetting resin such as epoxy resin. The prepreg 3P is usually formed into a roughly rectangular flat plate in a top view in which a thickness is about 0.2 mm to 2.0 mm and a length of one side is about 300 mm to 1000 mm, but the present invention is not limited thereto.

Next, the support metal foil provided metal foil 2 is mounted on a flat principal surface 3a of the prepreg 3P so that the metal foil lower surface 11a exposed in the groove portion 4 is opposed to the principal surface 3a of the prepreg 3P. At this time, a tip end of the positioning pin 52 projecting from the principal surface 3a of the prepreg 3P is inserted into the positioning hole 50 in the support metal foil provided metal foil 2 (refer to FIG. 1), so that the support metal foil provided metal foil 2 is positioned.

Next, as shown in FIG. 2B, the support metal foil provided metal foil 2 and the prepreg 3P are pressed and heated, the metal foil lower surface 11a exposed in the groove portion 4 is closely attached to the principal surface 3a of the prepreg 3P, and the prepreg 3P is thermally cured. Thus, the metal foil lower surface 11a exposed in the groove portion 4 is strongly fixed to a principal surface of the support board 3 provided after the prepreg 3P has been thermally cured, so that the support metal foil 1 can be prevented from peeling off the metal foil 11. As a result, stability in forming the laminated body 10 can be improved.

As an appropriate condition for the pressing and heating, a pressure is about 0.5 MPa to 9 MPa, a temperature is about 130° C. to 200° C., and a time is about 30 min to 120 min.

Next, as shown in FIG. 2C, the support metal foil provided metal foil 2 and the support board 3 located in the outside region of the groove portion 4 are cut away. Thus, the portion where the metal foil lower surface 11a and the principal surface of the support board 3 are strongly fixed to each other makes their end portions. Therefore, the support metal foil 1 can be prevented from peeling off the metal foil 11 at the end portions. Furthermore, the outside region of the groove portion 4 means a region located outside the frame-shaped groove portion 4, and at the time of cutting away, a little inner side of an outer periphery of the groove portion 4 may be cut.

Next, as shown in FIG. 2D, a first insulating layer 21 for interlayer insulation is laminated on an upper surface 11b of the metal foil (first conductor layer) 11 located in an inside region B of the groove portion 4. The inside region B of the groove portion 4 means a region surrounded by the frame-shape groove portion 4. In addition, an end portion of the first insulating layer 21 is located on a little outer side of the inside region B. This is because the first insulating layer 21 can be efficiently laminated on a predetermined position on the metal foil upper surface 11b. The first insulating layer 21 located on outer side of the inside region B is cut away as will be described below.

A material composing the first insulating layer 21 includes an electric insulating material prepared by diffusing an inorganic insulating filler such as silica or talc, in a thermosetting resin such as epoxy resin or bismaleimide triazine resin, an electric insulating material prepared by impregnating a glass cloth with a thermosetting resin, and the like.

This first insulating layer 21 may be formed in such a manner that a paste of a mixture prepared by diffusing an inorganic insulating filler in an uncured thermosetting resin such as epoxy resin or bismaleimide triazine resin is applied to the predetermined position on the metal foil upper surface 11b, and then thermally cured. In addition, it also may be formed in such a manner that a film of the above mixture or a prepreg prepared by impregnating a glass cloth with an uncured thermosetting resin is attached onto the predetermined position on the metal foil upper surface 11b, and then thermally cured.

Via-holes V are formed in the first insulating layer 21 to partially expose the metal foil 11. The via-holes V may be formed by for example laser processing. In addition, it also may be formed in such a manner that photosensitivity is given to the mixture for the first resin layer 21, and the mixture is exposed and developed by adopting the photolithography technique, but the present invention is not limited thereto.

Next, as shown in FIG. 2E, a second conductor layer 12 for a wiring conductor is formed into a predetermined pattern, on the surface of the first insulating layer 21 and in the via-holes V. The second conductor layer 12 may be composed of for example, a non-electrolytic copper-plated film and an electrolytic copper-plated film. The second conductor layer 12 is preferably formed by a well-known semi-additive method. The semi-additive method is superior in fine wiring, so that it is preferably used for efficiently manufacturing a thin and high density wiring board. More specifically, first, the surface of the first insulating layer 21 is roughened when needed, and the non-electrolytic copper-plated film is deposited on that surface so as to have a thickness of 0.1 μm to 2.0 μm. At this time, the non-electrolytic copper-plated film is also deposited on the metal foil upper surface 11b located in a region C provided from the end portion of the first insulating layer 21 to an outer edge so as to have the thickness of 0.1 μm to 2.0 μm.

Next, a plating resist layer having openings corresponding to the second conductor layer 12 is formed on the surface of the non-electrolytic copper-plated film deposited on the surface of the first insulating layer 21. This plating resist layer is formed by attaching a photosensitive resin film onto the non-electrolytic copper-plated film, and then exposing and developing the resin film by adopting the photolithography technique. Then, the electrolytic copper-plated film is deposited on the non-electrolytic copper-plated film which is exposed in the opening of the plating resist layer so as to have a thickness of about 5 μm to 30 μm.

At this time, the metal foil upper surface 11b located in the region C may be used as a charge supply electrode for supplying charges for the electrolytic plating. Therefore, a cathode of an electrolytic plating machine can be surely electrically connected through the metal foil upper surface 11b located in the region C.

Next, after the plating resist layer has been removed, the exposed portion of the non-electrolytic copper-plated film and electrolytic copper-plated film are etched as a whole until the non-electrolytic copper-plated film left between the electrolytic copper-plated films is disappeared, whereby the second conductor layer 12 is provided.

After the second conductor layer 12 has been formed as described above, as shown in FIG. 2F, second to fourth insulating layers 22 to 24 for interlayer insulation, and third to fifth conductor layers 13 to 15 for the wiring conductor are alternately and sequentially formed over the first insulating layer 21 and the second conductor layer 12, and a fifth insulating layer 25 for a solder resist is formed thereon, whereby the laminated body 10 for the wiring board is formed.

Each of the second to fourth insulating layers 22 to 24 for the interlayer insulation may be composed of the same electric insulating material as that of the first insulating layer 21, and formed by the same method as that of the first insulating layer 21. In addition, each of the third to fifth conductor layers 13 to 15 for the wiring conductors is preferably composed of the non-electrolytic copper-plated film and the electrolytic copper-plated film similar to the second conductor layer 12, and formed by the semi-additive method similar to the second conductor layer 12.

The fifth insulating layer 25 for the solder resist is composed of an electric insulating material prepared by for example, diffusing about 30% to 70% by mass of inorganic powder filler such as silica or talc, in an acrylic-modified epoxy resin. The fifth insulating layer 25 is preferably formed in such a manner that a photosensitive resin paste is applied to the fourth insulating layer 24 and the fifth conductor layer 15 by screen printing or roll coating so as to have a thickness of about 10 μm to 30 μm, exposed and developed into a predetermined pattern by adopting the photolithography technique, and then cured with ultraviolet light and heat. This photosensitive resin paste is prepared by mixing an inorganic insulating filler such as silica or talc in a mixture composed of a photosensitive resin such as acrylic-modified epoxy resin and a photopolymerization initiator or the like.

Next, as shown in FIGS. 2G and 2H, the laminated body 10 and the support board 3 located in the inside region B of the groove portion 4 are cut out in a direction shown by an arrow X. At this time, in order to efficiently cut them out, it is preferable that the laminated body 10, the support metal foil 1, and the support board 3 are cut out at a position provided 10 mm to 30 mm inside the groove portion 4, and a center portion of the laminated body 10 is left with the support metal foil 1 and the support board 3. Any cutting method may be used to the extent that the effect of the present invention is not hindered, and the cutting may be performed with for example dicing or a router apparatus.

Next, as shown in FIG. 21, the left laminated body 10 is separated from the support metal foil 1. At this time of separation, since the metal foil 11 is held on the support metal foil 1 with the release layer (not shown) interposed between them, the separation can be easily made without damaging the laminated body 10, only by tearing off the support metal foil 1 from the metal foil 11. That is, the support metal foil 1 functions as a boundary layer to facilitate the separation when the laminated body 10 is separated from the support board 3, so that the laminated body 10 can be easily separated from the support board 3 in a short time.

Next, as shown in FIG. 2J, the metal foil (first conductor layer) 11 is etched into a predetermined pattern to form the wiring conductor (external connection pad) on the surface of the first insulating layer 21. In order to etch the metal foil 11 into the predetermined pattern, for example an etching resist layer having a shape corresponding to the wiring conductor is formed on the surface of the metal foil 11, and the metal foil 11 exposed in the etching resist layer is etched away. In addition, the etching resist layer is formed into the shape corresponding to the wiring conductor in such a manner that a photosensitive resin film is attached onto the metal foil 11, and the resin film is exposed and developed by adopting the photolithography technique, and removed after etching the metal foil 11.

Finally, as shown in FIG. 2K, a sixth insulating layer 26 for a solder resist is formed on the surfaces of the etched metal foil 11 and the first insulating layer 21, whereby a wiring board 20 is provided. In addition, the sixth insulating layer 26 for the solder resist may be composed of the same material as that of the fifth insulating layer 25, and formed by the similar method as that of the fifth insulating layer 25.

Thus, according to this embodiment, the support metal foil provided metal foil 2 and the support board 3 are pressed so that the lower surface 11a of the metal foil 11 exposed in the groove portion 4 is closely attached to the principal surface of the support board 3, which are heated in this state to thermally cure the support board 3. Therefore, the lower surface 11a of the metal foil 11 exposed in the groove portion 4 and the principal surface of the support board 3 can be strongly fixed to each other, so that the stability in forming the laminated body 10 can be improved. Furthermore, the support metal foil 1 is not shrunk by heat applied when the support metal foil provided metal foil 2 and the support board 3 are pressed and heated, when the support board 3 is thermally cured, or in the step of laminating the insulating layers 21 to 25 and the conductor layers 12 to 15. As a result, even when the laminated body 10 and the support board 3 located in the inside region B of the groove portion 4 is cut out, the laminated body 10 and the support board 3 are not largely deflected, so that the subsequent process can be performed with accuracy and efficiency.

In the above, the one embodiment of the present invention has been described, but the present invention is not limited to the above-described embodiment, and various improvements and modifications can be made within the scope described in claim. For example, the description has been given to the case where the metal foil 11 is etched into the predetermined pattern and used as one part of the wiring conductor in the above embodiment, but for example, the metal foil 11 may be entirely etched away when needed as shown in FIG. 3. In this case, the conductor layer 12 exposed in the via-hole in the insulating layer 21 serves as the external connection pad.

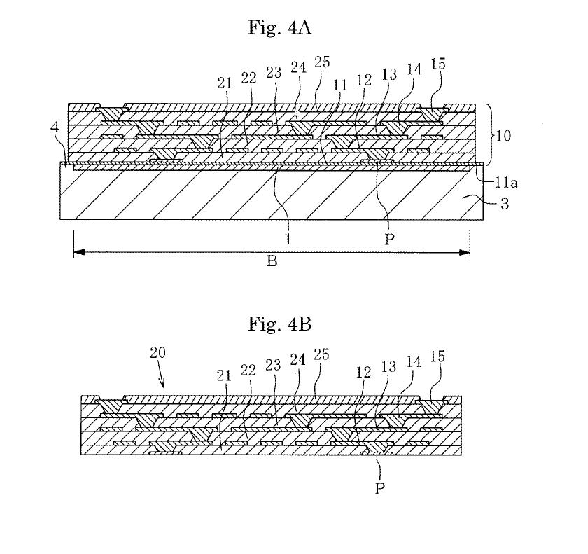

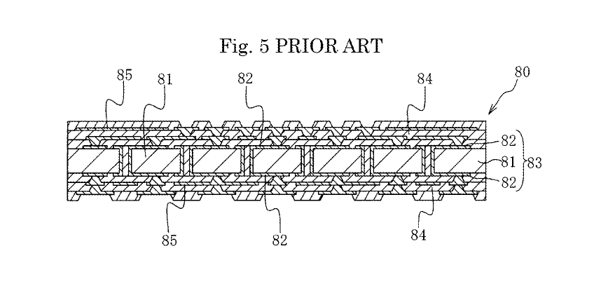

In addition, as another configuration as shown in FIG. 4A, an external connection pad P composed of for example copper is formed on a metal foil upper surface 11b located in the inside region B of the groove portion 4 by the semi-additive method or a full-additive method, and the insulating layers 21 to 25 and the conductor layers 12 to 15 are alternately laminated thereon to form the laminated body 10 for the wiring board including the pad P as its component. Then, the laminated body 10 is cut out and separated from the support metal foil 1, thereafter the metal foil 11 is entirely etched away to expose the pad P as shown in FIG. 4B. The configuration other than that is similar to the above-described embodiment.

What is claimed is:

1. A method for manufacturing a wiring board comprising steps of:
forming a groove portion in which a metal foil is exposed, by removing an outer periphery portion of a support metal foil in a shape of frame, the support metal foil holding the metal foil on one surface with a release layer interposed between them;
mounting the support metal foil provided metal foil having the groove portion, on a principal surface of a support board containing an uncured thermosetting resin in such a manner that the lower surface of the metal foil exposed in the groove portion is opposed to the principal surface of the support board;
pressing and heating the support metal foil provided metal foil and the support board to thermally cure the support board in a state in which the lower surface of the metal foil exposed in the groove portion is closely attached to the principal surface of the support board;
forming a laminated body for the wiring board by alternately laminating in plural, insulating layers and conductor layers, on the upper surface of the metal foil located at least in an inside region of the groove portion so as to be composed of the metal foil, the insulating layers, and the conductor layers;
cutting away the laminated body and the support board located in an outside region of the groove portion, from the laminated body and the support board located in an inside region of the groove portion; and
separating the laminated body from the support metal foil.

2. The method for manufacturing a wiring board according to claim 1, wherein
a positioning hole is formed in the outside region of the groove portion in the support metal foil provided metal foil.

3. The method for manufacturing a wiring board according to claim 1, wherein
the laminated body is formed on the upper surface of the metal foil located at least in the inside region of the groove portion after the support metal foil provided metal foil and the support board located in the outside region of the groove portion has been cut away.

4. The method for manufacturing a wiring board according to claim 1, wherein
the metal foil is etched into a predetermined pattern after the laminated body is separated from the support metal foil.

5. The method for manufacturing the wiring board according to claim 1, wherein
an external connection pad is formed on the metal foil,
a laminated body for the wiring board is formed by alternately laminating in plural, the insulating layers and the conductor layers on the metal foil having the pad formed, so as to be composed of the metal foil, the insulating layers, the conductor layers, and the pad, and
the pad is exposed by entirely etching away the metal foil after the laminated body has been separated from the support metal foil.
